(19) United States
(12) Patent Application Publication
(10) Pub. No.: US 2024/0306364 A1
(43) Pub. Date: Sep. 12, 2024

(54) SEMICONDUCTOR DEVICE AND FABRICATION METHOD THEREOF, MEMORY AND MEMORY SYSTEM

(71) Applicant: Yangtze Memory Technologies Co., Ltd., Wuhan (CN)

(72) Inventor: Zhaoyun Tang, Wuhan (CN)

(21) Appl. No.: 18/352,826

(22) Filed: Jul. 14, 2023

Related U.S. Application Data
(63) Continuation of application No. PCT/CN2023/080842, filed on Mar. 10, 2023.

(30) Foreign Application Priority Data
Mar. 10, 2023 (WO) PCT/CN2023/080842

(51) Int. Cl. H10B 12/00

(52) U.S. Cl. CPC H10B 12/05; H10B 12/30

(57) ABSTRACT

Examples of the present application disclose a semiconductor device and a fabrication method of the semiconductor device, a memory and a memory system. The method comprises: providing a substrate; forming a stop layer on a side of the substrate; forming a semiconductor layer on a side of the stop layer facing away from the substrate; forming first through-holes penetrating through the semiconductor layer and the stop layer; and forming gate structures on part of inner walls and part of bottoms of the first through-holes.

### CROSS-REFERENCE TO RELATED APPLICATION

This application claims priority to and the benefit of International Patent Application PCT/CN2023/080842, filed on Mar. 10, 2023, which is hereby incorporated by reference in its entirety.

### TECHNICAL FIELD

The present application relates to the technical field of semiconductors, and in particular to a semiconductor device and a fabrication method of the semiconductor device, a memory and a memory system.

### BACKGROUND

With the increasing demand for memory integration, the memory process becomes more and more difficult, and how to fabricate the memory to improve the performance of the memory has become an urgent issue to be addressed.

### BRIEF DESCRIPTION OF THE DRAWINGS

The drawings to be used in the description of examples be briefly introduced below in order to illustrate the technical solutions in the examples more clearly. The drawings described below are only some examples of the application. For those of ordinary skill in the art, other drawings may be obtained without creative work according to these drawings.

FIG. 1 is a structural schematic diagram of a memory provided by some examples;

FIG. 2 is a flow diagram of a fabrication method of a semiconductor device provided by examples of the present application;

FIGS. 3a to 3i are structural schematic diagrams of a fabrication method of a semiconductor device provided by examples of the present application;

FIG. 4 is a structural schematic diagram of a semiconductor device provided by examples of the present application;

FIG. 5 is another structural schematic diagram of a semiconductor device provided by examples of the present application;

FIG. 6 is a structural schematic diagram of a memory provided by examples of the present application; and

FIG. 7 is a structural schematic diagram of a memory system provided by examples of the present application.

### DETAILED DESCRIPTION

Specific structures and function details disclosed herein are merely representative, and are for the purpose of describing examples of the present application. However, the present application may be implemented specifically through many alternative forms, and should not be interpreted as being only limited to the examples set forth herein.

In the description of the present application, it is to be understood that the terms “center”, “lateral”, “upper”, “lower”, “left”, “right”, “vertical”, “horizontal”, “top”, “bottom”, “inner”, “outer”, etc. indicate orientation or position relationships that are based on the orientations or position relationships as shown in the figures, which are only intended to facilitate description of the present application and to simplify the description, instead of indicating or implying the device or element indicated must have a specific orientation and be configued and operated in a specific orientation, and thus cannot be understood as limitations on the present application. Furthermore, the terms “first” and “second” are only for the purpose of description, and cannot be construed as indicating or implying relative importance or implicitly indicating the number of indicated technical features. Thus, features defined by “first” and “second” may explicitly or implicitly include one or more of such features. In the description of the present application, “a plurality of” means two or more, unless otherwise stated. In addition, the term “comprise” and any variants thereof are intended to cover the non-exclusive “including”.

In the description of the present application, it is to be noted that, unless otherwise specified and defined expressly, the terms “connected” and “connecting” should be understood broadly, which, for example, may be fixed connection, detachable connection, or integrated connection; may be either mechanical connection or electrical connection; may be either direct connection or indirect connection through intermediate media, and may be connection inside two elements. Those of ordinary skill in the art may understand the specific meanings of the above-mentioned terms in the present application according to specific conditions.

The terms as used herein are only used to describe the specific examples, and are not intended to limit the examples. Unless otherwise indicated expressly in the context, the singular forms “a” and “an” used herein are also intended to include plurality. It should also be understood that the terms “comprise” and/or “include”, as used herein, specify the presence of the stated features, integers, steps, operations, units and/or components, and do not preclude the presence or addition of one or more of other features, integers, steps, operations, units, components, and/or a combination thereof.

A dynamic random access memory (DRAM) consists of a plurality of memory cells, each of which consists of storage capacitors manipulated by one transistor.

During the formation of gates in a transistor, first, a plurality of grooves are formed by etching in a semiconductor layer, wherein an initial gate layer is formed at a sidewall and a bottom of each groove; and then part of the initial gate layer at the sidewall and the bottom of the groove is etched to form two gates. That is, each groove has two gates disposed face to face therein. However, due to limitations of an etching process, it is easy to cause inconsistent etching depths of different grooves, resulting in inconsistent dimensions of the initial gate layer in different grooves in a depth direction, which further causes the depths and bottom dimensions of the grooves to be difficult to control precisely and increases the difficulty of etching the initial gate layer into the gates.

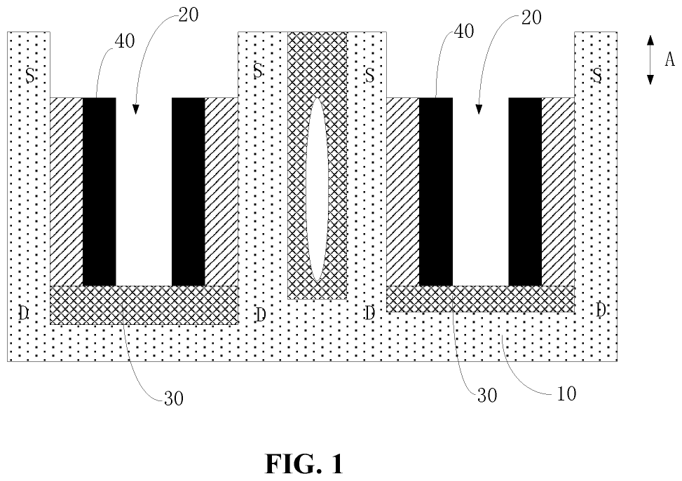

In some examples, as shown in FIG. 1, after a plurality of grooves 20 are formed in a semiconductor layer 10, first, an insulating layer 30 is formed at the bottom of each of grooves 20 (the insulating layers 30 in the grooves 20 of different depths are different in thickness), so that the depths of all the grooves 20 are consistent, that is, the upper surfaces of all the insulating layers 30 are flush. Then, an initial gate layer is formed in the grooves 20, and is etched into two gates 40. Such a way of fabrication can increase the dimension uniformity of the gates 40 in a depth direction (i.e., a direction A) and further improves the performance of the memory. However, the thickness of the insulating layer 30 in each of grooves 20 is difficult to control precisely, and the fabrication difficulty is still high.

Based on this, examples of the present application provide a fabrication method of a semiconductor device.

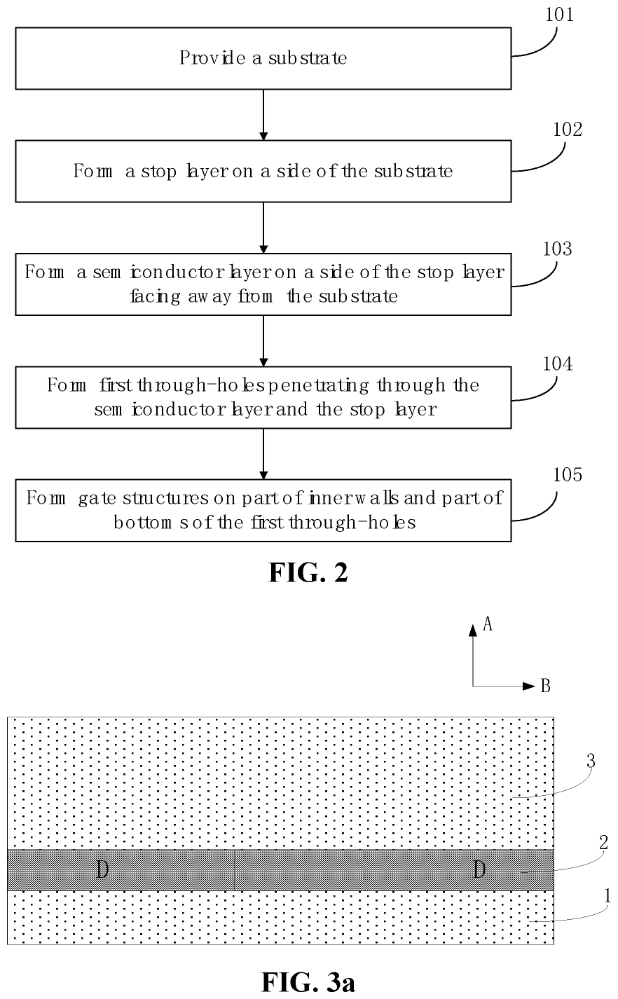

Refer to FIG. 2, which is a flow diagram of a fabrication method of a semiconductor device provided by the examples of the present application.

As shown in FIG. 2, the fabrication method of the semiconductor device provided by the examples of the present application comprises 101 to 105, specifically as follows:

### 101: Providing a Substrate

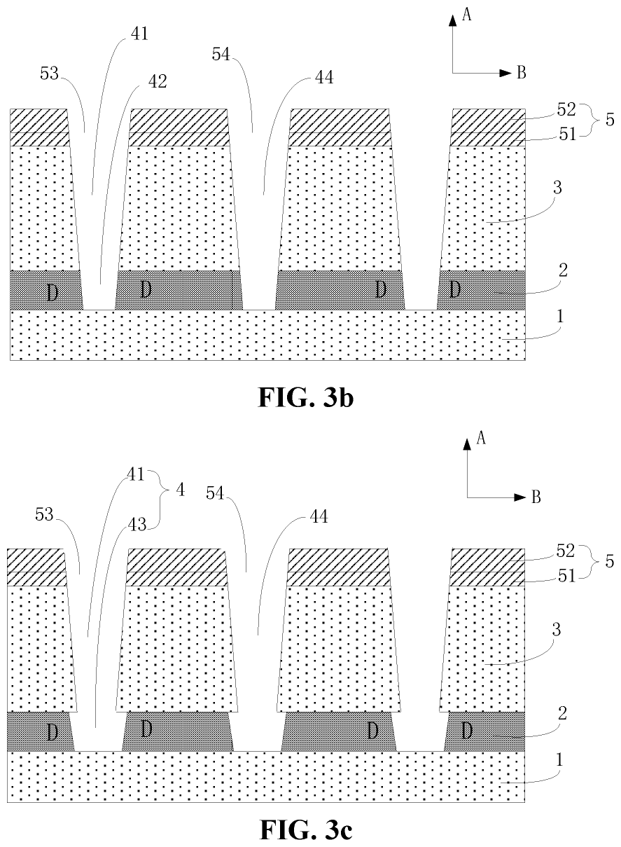

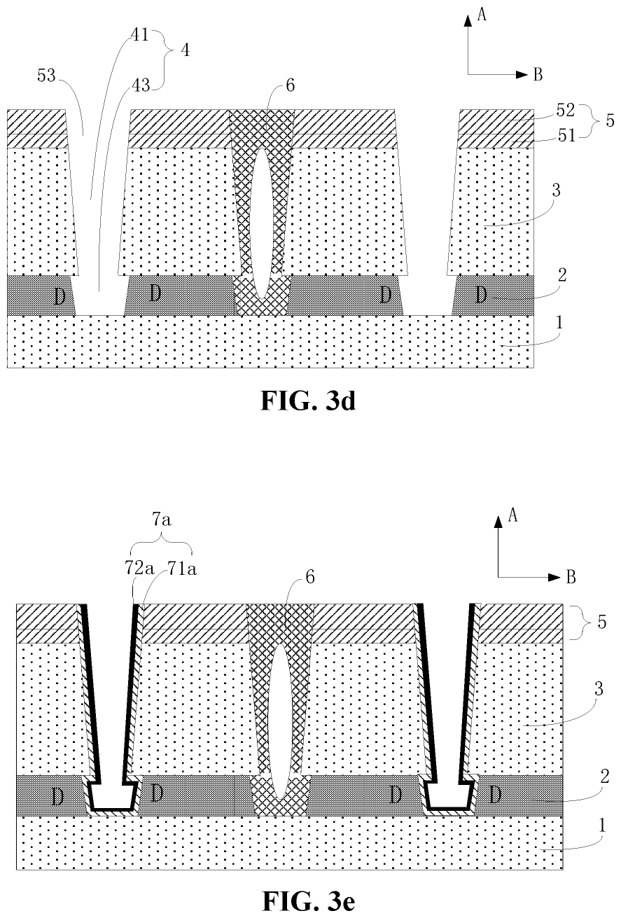

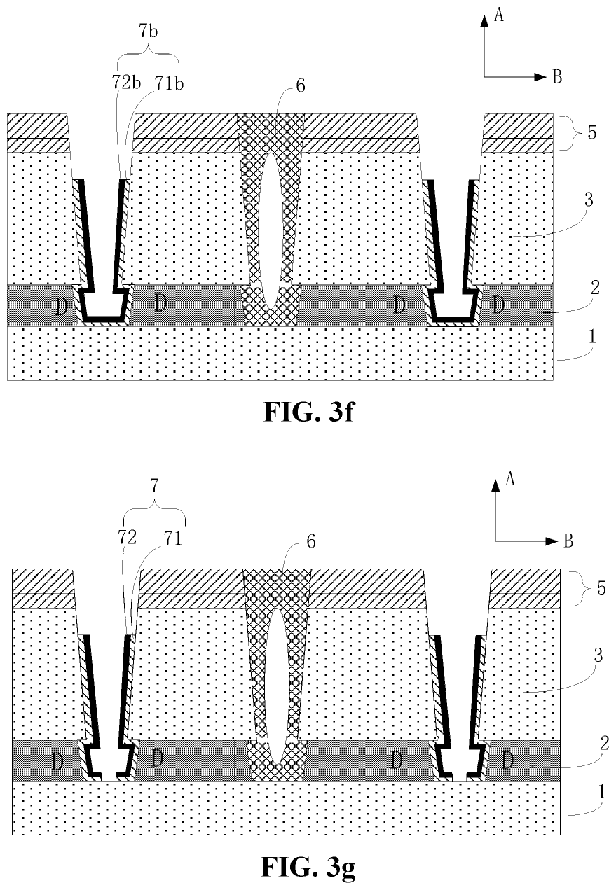

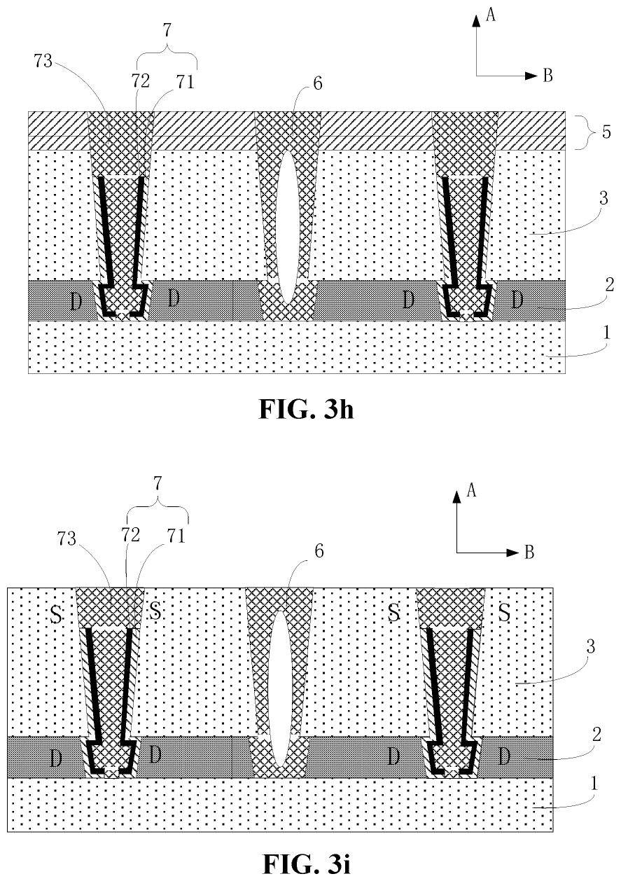

As shown in FIG. 3a, the substrate 1 may be a single-layer structure, and may also be a multi-layer composite structure. For example, the substrate 1 may comprise at least one of monocrystalline silicon, polycrystalline silicon, monocrystalline germanium, a group III-V compound semiconductor material, a group II-VI compound semiconductor material, or other semiconductor materials. In addition, the substrate 1 may be removed or replaced by other film layers in subsequent fabrication processes, which is not limited specifically herein.

### 102: Forming a Stop Layer on a Side of the Substrate

As shown in FIG. 3a, the stop layer 2 is formed on a side of the substrate 1 using a thin film deposition process. The thin film deposition process may be physical vapor deposition, chemical vapor deposition, atomic layer deposition, laser assisted deposition, and the like. The stop layer 2 may be an etching stop layer for first through-holes in subsequent processes. The stop layer 2 may comprise at least one of monocrystalline silicon, polycrystalline silicon, monocrystalline germanium, and silicon germanium. The material of the stop layer 2 may be different from the material of the substrate 1 such that the etching rates of the stop layer 2 and the substrate 1 are different, thereby easily controlling the subsequent first through-holes to stop at the stop layer, i.e., ensuring that the subsequent first through-holes may just penetrate through the stop layer 2 and does not extend into the substrate 1. For example, the substrate 1 may be monocrystalline silicon, and the stop layer 2 may be silicon germanium.

The stop layer 2 comprises drains D. The drains D are formed by growing a plurality of epitaxial layers, performing ion doping and full activation while growing the epitaxial layers, and controlling the concentration distribution of doping; and at the same time the drains D may serve as the stop layer 2 for etching the first through-holes.

In this example, the stop layer 2 serves as the etching stop layer for the first through-holes, so that each first through-hole stops at the stop layer 2, thereby increasing the uniformity of the depths of the first through-holes (i.e., the dimensions of the first through-holes 4 in a first direction A), effectively enlarging the process window of film layers subsequently formed in the first through-holes (the process window of the film layers in the first through-holes may be limited if the depths of the first through-holes are different), and further improving the structure stability of the semiconductor device. At the same time, the stop layer 2 serves as the drain D. That is, ion implantation has been completed when the stop layer 2 is formed. There is no need to perform the ion implantation on the film layer from the backside (i.e., a side of the substrate 1 facing away from the stop layer 2) subsequently, thereby reducing a thermal budget of a backside process and at the same time avoiding affecting a high dielectric constant material layer subsequently formed on the front side (i.e., a side of the stop layer 2 facing away from the substrate 1).

### 103: Forming a Semiconductor Layer on a Side of the Stop Layer Facing Away From the Substrate

As shown in FIG. 3a, the semiconductor layer 3 is formed on the side of the stop layer 2 facing away from the substrate 1 using a thin film deposition process. The semiconductor layer 3 may serve as a channel layer of the transistor. The semiconductor layer 3 may comprise at least one of monocrystalline silicon, polycrystalline silicon, monocrystalline germanium, and silicon germanium. The materials of the semiconductor layer 3 and the stop layer 2 may be the same, and may also be different. The materials of the semiconductor layer 3 and the substrate 1 may be the same, and may also be different.

### 104: Forming First Through-holes Penetrating Through the Semiconductor Layer and the Stop Layer

The first through-holes penetrate through the semiconductor layer 3 and the stop layer 2 along a first direction A that is a direction perpendicular to the upper surface of the substrate 1 (i.e., a surface of a side of the substrate 1 close to the stop layer 2). The number of the first through-holes may be multiple, and multiple first through-holes are disposed at intervals. Due to the disposition of the stop layer 2, each of the first through-holes can just penetrate through the semiconductor layer 3 and the stop layer 2 along the first direction A, and does not extend into the substrate 1, thereby increasing the uniformity of the depths of the first through-holes (i.e., the dimensions of the first through-holes 4 along the first direction).

Specifically, forming the first through-holes penetrating through the semiconductor layer and the stop layer comprises: forming a mask layer on a side of the semiconductor layer facing away from the substrate, wherein the mask layer comprises openings; and forming, through the openings, the first through-holes penetrating through the semiconductor layer and the stop layer. As shown in FIG. 3b, a mask layer 5 is first formed on the side of the semiconductor layer 3 facing away from the substrate 1. The mask layer 5 may be a multi-layer structure. For example, the mask layer 5 may comprise a hard mask layer 51 and a photoresist layer 52, wherein the hard mask layer 51 is located on the side of the semiconductor layer 3 facing away from the substrate 1, and the photoresist layer 52 is located on a side of the hard mask layer 51 facing away from the substrate 1.

The mask layer 5 has openings 53 therein. The semiconductor layer 3 and the stop layer 2 are etched using an etching process through the openings 53 to form the first through-holes 4 penetrating through the semiconductor layer 3 and the stop layer 2. The number of the openings 53 may be multiple in order to form multiple first through-holes 4 corresponding to the multiple openings 53 one to one.

In one implementation, the first through-holes 4 comprise first sub-holes 41 and second sub-holes 42 that are connected together. The semiconductor layer 3 is etched through the openings 53 in the mask layer 5 to form the first sub-holes 41, and the stop layer 2 is etched to form the second sub-holes 42, such that the first sub-holes 41 and the second sub-holes 42 constitute the first through-holes 4. The first sub-holes 41 penetrate through the semiconductor layer 3 along the first direction A, and the second sub-holes 42 penetrate through the stop layer 2 along the first direction A. Sidewalls of the first sub-holes 41 are flush with sidewalls of the second sub-holes 42. That is, dimensions of ends of the first sub-holes 41 close to the second sub-holes 42 are the same as dimensions of ends of the second sub-holes 42 close to the first sub-holes 41. The ends of the first sub-holes 41 close to the second sub-holes 42 may be circular, and the dimensions of the ends of the first sub-holes 41 close to the second sub-holes 42 may be diameters. The ends of the second sub-holes 42 close to the first sub-holes 41 may be circular, and the dimensions of the ends of the second sub-holes 42 close to the first sub-holes 41 may be diameters.

In another implementation, the first through-holes 4 comprise first sub-holes 41 and third sub-holes 43 that are connected together. Specifically, forming the first through-holes penetrating through the semiconductor layer and the stop layer comprises: forming the first sub-holes penetrating through the semiconductor layer and second sub-holes penetrating through the stop layer; and etching the stop layer exposed in the second sub-holes to form the third sub-holes, wherein dimensions of ends of the third sub-holes close to the first sub-holes are greater than dimensions of ends of the first sub-holes close to the third sub-holes.

As shown in FIG. 3b, the semiconductor layer 3 is etched first through the openings 53 in the mask layer 5 to form the first sub-holes 41, and the stop layer 2 is etched to form the second sub-holes 42. The first sub-holes 41 penetrate through the semiconductor layer 3 along the first direction A, and the second sub-holes 42 penetrate through the stop layer 2 along the first direction A. Sidewalls of the first sub-holes 41 are flush with sidewalls of the second sub-holes 42. That is, dimensions of ends of the first sub-holes 41 close to the second sub-holes 42 are the same as dimensions of ends of the second sub-holes 42 close to the first sub-holes 41.

Then, as shown in FIG. 3c, the stop layer 2 exposed in the second sub-holes 42 continues to be etched using an etching process to enlarge the second sub-holes 42 into the third sub-holes 43, such that the first sub-holes 41 and the third sub-holes 43 constitute the first through-holes 4. Sidewalls of the third sub-holes 43 are not flush with the sidewalls of the first sub-holes 41, and dimensions of ends of the third sub-holes 43 close to the first sub-holes 41 are greater than dimensions of ends of the first sub-holes 41 close to the third sub-holes 43. The ends of the first sub-holes 41 close to the third sub-holes 43 may be circular, and the dimensions of the ends of the first sub-holes 41 close to the third sub-holes 43 may be diameters. The ends of the third sub-holes 43 close to the first sub-holes 41 may be circular, and the dimensions of the ends of the third sub-holes 43 close to the first sub-holes 41 may be diameters.

Due to the limitations of the etching process, sections of the first sub-holes 41 and the second sub-holes 42 formed by etching along the first direction A are inverted trapezoidal, that is, dimensions of ends of the second sub-holes 42 facing away from the first sub-holes 41 are less than dimensions of ends of the first sub-holes 41 facing away from the second sub-holes 42. When each of the initial gate structures in the first through-holes 4 is etched into two gate structures subsequently, the initial gate structures not required to be etched at the sidewalls of the second sub-holes 42 are susceptible to damages due to the smaller dimensions of the second sub-holes 42. In this example, the second sub-holes 42 are enlarged into the third sub-holes 43, thereby avoiding the damages to the initial gate structures not required to be etched at the sidewalls of the third sub-holes 43.

In order to isolate adjacent transistors, there is also a need to form an isolation structure between the adjacent transistors. Specifically, the method further comprises: forming a second through-hole penetrating through the semiconductor layer and the stop layer while forming the first through-holes, wherein the second through-hole is located between two adjacent ones of the first through-holes.

The second through-hole 44 and the first through-holes 4 are formed at the same time, and the second through-hole 44 is located between two adjacent first through-holes 4. As shown in FIG. 3b, the mask layer 5 further has an opening 54 therein, and the opening 54 is the same as the openings 53 in size and shape. While the first through-holes 4 are formed by etching in the semiconductor layer 3 and the stop layer 2 through the openings 53, the second through-hole 44 is formed by etching in the semiconductor layer 3 and the stop layer 2 through the opening 54, that is, the second through-hole 44 penetrates through the semiconductor layer 3 and the stop layer 2 along the first direction A. The number of the openings 54 may be multiple such that multiple second through-holes 44 corresponding to the multiple openings 54 one to one are formed through the multiple openings 54. As shown in FIG. 3c, the second through-hole 44 is the same as the first through-holes 4 in size and shape, which is no longer repeated in detail here.

As shown in FIG. 3d, an isolation structure 6 may be formed in the second through-hole 44 after the second through-hole 44 is formed. Specifically, the isolation structure 6 is formed in the second through-hole 44 using a thin film deposition process. Since at this point the mask layer 5 has not been removed, the isolation structure 6 is also formed in the opening 54 of the mask layer 5. The isolation structure 6 may comprise a combination of any one or more of silicon oxide, silicon nitride, and silicon oxynitride, etc.

### 105, Forming Gate Structures on Part of Inner Walls and Part of Bottoms of the First Through-holes

The first through-hole 4 has two gate structures therein. The two gate structures are insulated and disposed at an interval, and each gate structure is located on part of the inner wall and part of the bottom of the first through-hole 4.

Specifically, forming the gate structures on part of the inner walls and part of the bottoms of the first through-holes comprises: forming initial gate structures on the inner walls and the bottoms of the first through-holes, the bottoms of the first through-holes being ends of the first through-holes close to the substrate; removing part of the initial gate structures on the inner walls of the first through-holes to obtain remaining initial gate structures, the part of the initial gate structures being located at ends of the initial gate structures facing away from the substrate; and removing part of the remaining initial gate structures on the inner walls and the bottoms of the first through-holes to separate each of the remaining initial gate structures into two gate structures.

As shown in FIG. 3e, the initial gate structures 7a are formed on the inner walls and the bottoms of the first through-holes 4 using a thin film deposition process, and cover the entire inner walls and the bottoms of the first through-holes 4. The initial gate structures 7a comprise an initial gate oxidization layer 71a and an initial gate layer 72a, wherein the initial gate oxidization layer 71a covers the entire inner walls and the bottoms of the first through-holes 4, and the initial gate layer 72a covers the surface of the initial gate oxidization layer 71a. Since at this point the mask layer 5 has not been removed, the initial gate structures 7a also cover inner walls of the openings 53 in the mask layer 5.

Then, as shown in FIG. 3f, part of the initial gate structures on the inner walls of the first through-holes 4 are removed using an etching process. This part of the initial gate structures is part of the initial gate structures at the top (i.e., ends of the initial gate structures 7a facing away from the substrate 1) of the initial gate structures 7a. That is, part of the initial gate oxidization layer 71a and part of the initial gate layer 72a at the top of the initial gate structures 7a are removed, in order to form sources S in the semiconductor layer 3 on peripheral sides of this part of the initial gate structures subsequently. In addition, the initial gate structures in the openings 53 are removed while removing this part of the initial gate structures.

The remaining initial gate structures 7b are obtained after removing this part of the initial gate structures from the initial gate structures 7a, and comprise a remaining initial gate oxidization layer 71b and a remaining initial gate layer 72b. As shown in FIG. 3g, part of the remaining initial gate structures are removed from the inner walls and the bottoms of the first through-holes 4 using an etching process to separate each of the remaining initial gate structures 7b into two gate structures 7, that is, each of the first through-holes 4 has two gate structures 7 therein that are disposed face to face along a second direction B. The two gate structures 7 are insulated and disposed at an interval, and each gate structure 7 covers part of the inner walls of the first through-hole 4, and may also cover part of the bottom of the first through-hole 4.

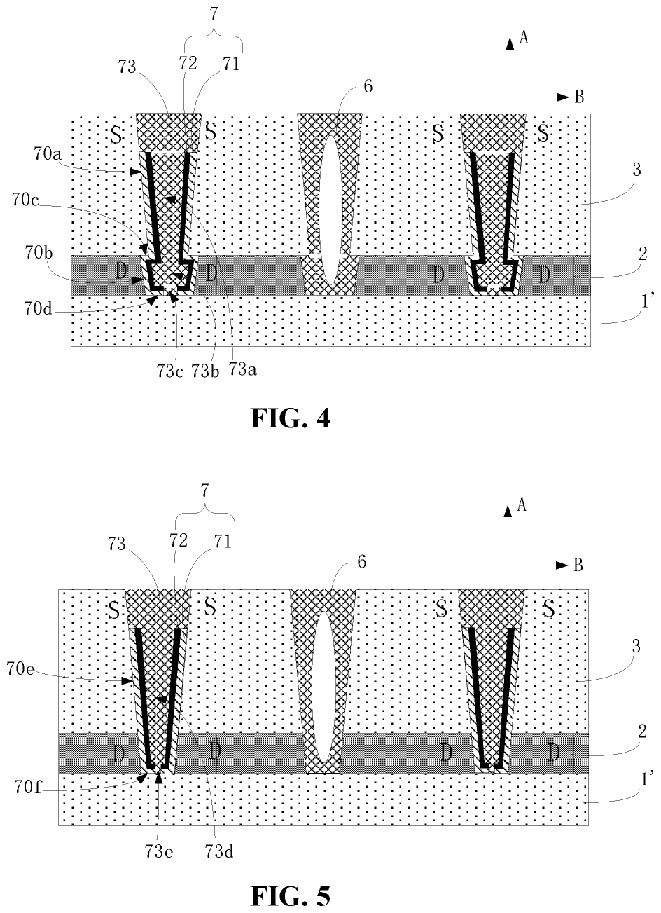

In conjunction with what is shown in FIG. 4, when the first through-holes 4 comprise the first sub-holes 41 and the third sub-holes 43, the gate structures 7 may comprise first substructures 70a extending in the semiconductor layer 3 along the first direction A, second substructures 70b extending in the stop layer 2 along the first direction A, and third substructure 70c and fourth substructures 70d that extend in the stop layer 2 along the second direction B. The first direction A intersects the second direction B, for example, the first direction A is perpendicular to the second direction B. An end of the first substructure 70a is connected with an end of the third substructure 70c. An end of the third substructure 70c facing away from the first substructure 70a is connected with an end of the second substructure 70b. An end of the second substructure 70b facing away from the third substructure 70c is connected with an end of the fourth substructure 70d.

The first substructures 70a cover part of the inner walls of the first sub-holes 41 (i.e., the first substructures 70a cover part of the semiconductor layer 3 exposed in the first sub-holes 41). The third substructures 70c cover the semiconductor layer 3 exposed in the third sub-holes 43. The second substructures 70b cover the inner walls of the third sub-holes 43 (i.e., the second substructures 70b cover the stop layer 2 exposed in the third sub-holes 43). The fourth substructures 70d cover the bottoms of the third sub-holes 43 (i.e., the fourth substructures 70d cover the substrate 1 exposed in the third sub-holes 43).

In conjunction with what is shown in FIG. 5, when the first through-holes 4 comprise the first sub-holes 41 and the second sub-holes 42, the gate structures 7 may comprise fifth substructures 70e extending in the semiconductor layer 3 and the stop layer 2 along the first direction A, and sixth substructures 70f extending in the stop layer 2 along the second direction B. The fifth substructures 70e cover part of the inner walls of the first sub-holes 41 (i.e., the fifth substructures 70e cover part of the semiconductor layer 3 exposed in the first sub-holes 41) and the inner walls of the second sub-holes 42 (i.e., the fifth substructures 70e cover the stop layer 2 exposed in the second sub-holes 42). The sixth substructures 70f cover the bottoms of the second sub-holes 42 (i.e., the sixth substructures 70f cover the substrate 1 exposed in the second sub-holes 42).

The gate structures 7 comprise a gate oxidization layer 71 on part of the inner walls and part of the bottoms of the first through-holes 4, and a gate layer 72 on a side of the gate oxidization layer 71 facing away from the semiconductor layer 3. When the gate structures 7 comprise first substructures 70a to fourth substructures 70d, the first substructures 70a to the fourth substructures 70d each comprises part of the gate oxidization layer 71 and part of the gate layer 72. When the gate structures 7 comprise fifth substructures 70e and sixth substructures 70f, the fifth substructures 70e and the sixth substructures 70f each comprises part of the gate oxidization layer 71 and part of the gate layer 72. The gate oxidization layer 71 comprises a combination of any one or more of silicon oxide, silicon nitride, and silicon oxynitride, etc. The gate layer 72 comprises a combination of any one or more of tungsten, cobalt, copper, aluminum and the like.

After forming the gate structures 7, the method further comprises: forming spacing portions within the first through-holes.

As shown in FIG. 3h, a spacing portion 73 is filled in the first through-hole 4 using a thin film deposition process to ensure that the two gate structures 7 in the first through-hole 4 are spaced apart. Since at this point the mask layer 5 has not been removed, the spacing portions 73 are also located in the openings 53 in the mask layer 5. The spacing portions 73 comprise a combination of any one or more of silicon oxide, silicon nitride, and silicon oxynitride, etc.

Further, after forming the gate structures on part of the inner walls and part of the bottoms of the first through-holes, the method further comprises: removing the mask layer.

As shown in FIG. 3i, the mask layer 5 may be removed using a chemical mechanical polishing process, and the spacing portions 73 in the openings 53 and the isolation structure 6 in the opening 54 of the mask layer 5 are removed at the same time, such that upper surfaces of the remaining spacing portions 73 (i.e., surfaces of sides of the remaining spacing portions 73 facing away from the substrate 1) and an upper surface of the remaining isolation structure 6 (i.e., a surface of a side of the remaining isolation structures 6 facing away from the substrate 1) are flush with the upper surface of the semiconductor layer 3 (i.e., a surface of a side of the semiconductor layer 3 facing away from the substrate 1).

Further, the method also comprises: forming sources in the semiconductor layer, wherein the sources are located on a side of the semiconductor layer facing away from the substrate.

As shown in FIG. 3i, after removing the mask layer 5, ions may be doped in the semiconductor layer 3 using an ion implantation process to form the sources S that are located on the side of the semiconductor layer 3 facing away from the substrate 1. Each gate structure 7 corresponds to one source S such that each gate structure 7 and the corresponding source S and drain D constitute one transistor.

The fabrication method of the semiconductor device provided by the examples of the present application can form the stop layer on a side of the substrate, form the semiconductor layer on the side of the stop layer facing away from the substrate to form the first through-holes penetrating through the semiconductor layer and the stop layer, and form the gate structures on part of the inner walls and part of the bottoms of the first through-holes. The disposition of the stop layer can increase the uniformity of the depths of the first through-holes, thereby increasing the uniformity of the dimensions of the gate structures in the first through-holes, improving the performance of the memory and reducing the fabrication difficulty.

Accordingly, the examples of the present application further provide a semiconductor device which can be formed using the above-mentioned fabrication method of the semiconductor device.

As shown in FIGS. 4 and 5, the semiconductor device provided by this example comprises a base 1′, a stop layer 2, a semiconductor layer 3 and gate structures 7. The structures of the base 1′ and the substrate 1 in the above-mentioned example may be the same, and may also be different. The structure of the base 1′ may be set according to actual process demands, which is not defined specifically herein.

The stop layer 2 is located on a side of the base 1′. The stop layer 2 comprises drains D. The disposition of the stop layer 2 effectively increases the dimension uniformity of the gate structures 7 in the first direction A, and the stop layer 2 serves as the drains D, effectively reducing a thermal budget. The stop layer 2 comprises at least one of monocrystalline silicon, polycrystalline silicon, monocrystalline germanium, and silicon germanium.

The semiconductor layer 3 is located on a side of the stop layer 2 facing away from the base 1′. The semiconductor layer 3 may serve as a channel layer of a transistor. The semiconductor layer 3 may comprise at least one of monocrystalline silicon, polycrystalline silicon, monocrystalline germanium, and silicon germanium. The materials of the semiconductor layer 3 and the stop layer 2 may be the same and may also be different. For example, the semiconductor layer 3 may be monocrystalline silicon, and the stop layer 2 may be silicon germanium.

The gate structures 7 extend in the semiconductor layer 3 along a first direction A and penetrate through the stop layer 2. The number of the gate structures 7 may be multiple. The multiple gate structures 7 are insulated and disposed at intervals. Every two of the multiple gate structures 7 may constitute a set of gate structures, and the two gate structures 7 in each set of gate structures are disposed face to face along a second direction B.

In one implementation, as shown in FIG. 4, the gate structures 7 comprise first substructures 70a extending in the semiconductor layer 3 along the first direction A, second substructures 70b extending in the stop layer 2 along the first direction A, and third substructures 70c and fourth substructures 70d that extend in the stop layer 2 along the second direction B. The first direction A intersects the second direction B, for example, the first direction A is perpendicular to the second direction B. An end of the first substructure 70a is connected with an end of the third substructure 70c. An end of the third substructure 70c facing away from the first substructure 70a is connected with an end of the second substructure 70b. An end of the second substructure 70b facing away from the third substructure 70c is connected with an end of the fourth substructure 70d.

In each set of gate structures, the third substructure 70c in one gate structure 7 is located on a side of the first substructure 70a of the gate structure 7 facing away from the other gate structure 7, that is, the third substructure 70c in the gate structure 7 extends in a direction facing away from the other gate structure 7. In addition, the fourth substructure 70d in the gate structure 7 is located on a side of the second substructure 70b in the gate structure 7 close to the other gate structure 7, that is, the fourth substructure 70d in the gate structure 7 extends in a direction facing the other gate structure 7.

In another implementation, as shown in FIG. 5, the gate structures 7 may comprise fifth substructures 70e extending in the semiconductor layer 3 and the stop layer 2 along the first direction A, and sixth substructures 70f extending in the stop layer 2 along the second direction B. An end of the sixth substructure 70f is connected with an end of the fifth substructure 70e.

In each set of gate structures, the sixth substructure 70f in one gate structure 7 is located on a side of the fifth substructure 70e in the gate structure 7 close to the other gate structure 7, that is, the sixth substructure 70f in the gate structure 7 extends in a direction facing the other gate structure 7.

The gate structures 7 comprise a gate oxidization layer 71 extending in the semiconductor layer 3 along the first direction A and penetrating through the stop layer 2, and a gate layer 72 located on a side of the gate oxidization layer 71 facing away from the semiconductor layer 3. When the gate structures 7 comprise first substructures 70a to fourth substructures 70d, the first substructures 70a to the fourth substructures 70d each comprises part of the gate oxidization layer 71 and part of the gate layer 72. When the gate structures 7 comprise fifth substructures 70e and sixth substructures 70f, the fifth substructures 70e and the sixth substructures 70f each comprises part of the gate oxidization layer 71 and part of the gate layer 72. The gate oxidization layer 71 comprises a combination of any one or more of silicon oxide, silicon nitride, and silicon oxynitride, etc. The gate layer 72 comprises a combination of any one or more of tungsten, cobalt, copper, aluminum and the like.

The semiconductor device further comprises spacing portions 73. The spacing portions 73 extend in the semiconductor layer 3 and the stop layer 2 along the first direction A. The gate structures 7 cover part of sidewalls and part of bottoms of the spacing portions 73. The bottoms of the spacing portions 73 are ends of the spacing portions 73 close to the base 1′. The spacing portion 73 is located between the two gate structures 7 in each set of gate structures to space apart the two gate structures 7 in each set of gate structures. The spacing portions 73 comprise a combination of any one or more of silicon oxide, silicon nitride, and silicon oxynitride, etc.

In one implementation, as shown in FIG. 4, the spacing portions 73 comprise first spacing sub-portions 73a penetrating through the semiconductor layer 3, and second spacing sub-portions 73b extending in the stop layer 2 along the first direction A. Dimensions of ends of the second spacing sub-portions 73b close to the first spacing sub-portions 73a in the second direction B are greater than dimensions of ends of the first spacing sub-portions 73a close to the second spacing sub-portions 73b in the second direction B. In one set of gate structures, the first spacing sub-portion 73a is located between the two first substructures 70a in the set of gate structures, and the second spacing sub-portion 73b is located between the two second substructures 70b in the set of gate structures.

The spacing portions 73 may further comprise third spacing sub-portions 73c extending in the stop layer 2 along the first direction A, and the third spacing sub-portions 73c are located between the second spacing sub-portions 73b and the base 1′. Dimensions of ends of the third spacing sub-portions 73c close to the second spacing sub-portions 73b in the second direction B are less than dimensions of ends of the second spacing sub-portions 73b close to the third spacing sub-portions 73c in the second direction B. In one set of gate structures, the third spacing sub-portion 73c is located between the two fourth substructures 70d in the set of gate structures.

In another implementation, as shown in FIG. 5, the spacing portions 73 comprise fourth spacing sub-portions 73d penetrating through the semiconductor layer 3 and extending in the stop layer 2 along the first direction A, and fifth spacing sub-portions 73e extending in the stop layer 2 along the second direction B. The fifth spacing sub-portions 73e are located between the fourth spacing sub-portions 73d and the base 1′. Dimensions of ends of the fifth spacing sub-portions 73e close to the fourth spacing sub-portions 73d in the second direction B are less than dimensions of ends of the fourth spacing sub-portions 73d close to the fifth spacing sub-portions 73e in the second direction B. In one set of gate structures, the fourth spacing sub-portion 73d is located between the two fifth substructures 70e in the set of gate structures, and the fifth spacing sub-portion 73e is located between the two sixth substructures 70f in the set of gate structures.

The semiconductor layer 3 comprises sources S that are located on a side of the semiconductor layer 3 facing away from the base 1′. Each gate structure 7 corresponds to one source S such that each gate structure 7 and the corresponding source S and drain D constitute one transistor.

The semiconductor device further comprises isolation structures 6 that penetrate through the semiconductor layer 3 and the stop layer 2. The number of the isolation structures 6 may be multiple. The transistors corresponding to each set of gate structures may constitute a set of transistors. The isolation structures 6 may be located between two adjacent sets of transistors to isolate the two adjacent sets of transistors. The isolation structures 6 are the same as one set of gate structures and the spacing portion 73 between the set of gate structures in overall size and shape. The isolation structures 6 may comprise a combination of any one or more of silicon oxide, silicon nitride, and silicon oxynitride, etc.

Examples of the present application provide a semiconductor device. By disposing a stop layer located on a side of the base, a semiconductor layer located on a side of the stop layer facing away from the base and the gate structures penetrating through the semiconductor layer and the stop layer, the uniformity of the dimensions of the gate structures is increased, the performance of the memory is improved, and the fabrication difficulty is reduced.

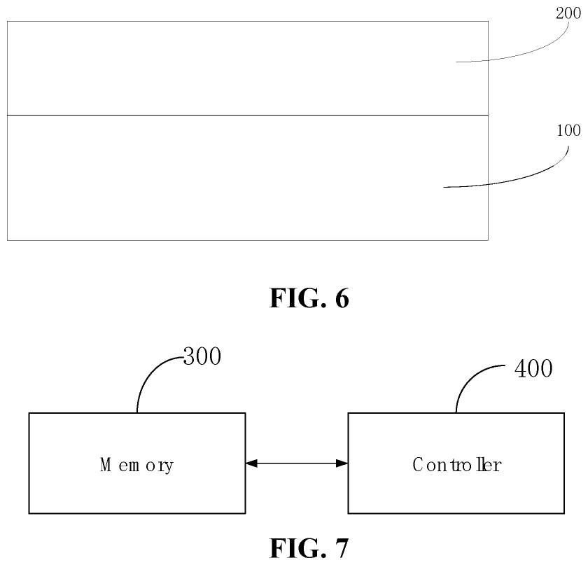

Refer to FIG. 6 which is a structural schematic diagram of a memory provided by examples of the present application.

As shown in FIG. 6, the memory comprises a memory array 100, and a periphery device 200 connected with the memory array 100. The memory array 100 may comprise the semiconductor device in the above-mentioned examples, which is no longer repeated in detail here.

The memory array 100 may be a non-volatile memory array. For example, the memory array 100 may be a NAND flash, a NOR flash, etc. The periphery device 200 may comprise a device such as a CMOS (Complementary Metal Oxide Semiconductor), an SRAM (Static Random-Access Memory), a DRAM (Dynamic Random Access Memory), an FPGA (Field-Programmable Gate Array), a CPU (Central Processing Unit), an Xpoint chip, etc.

Specifically, the periphery device 200 may be located on the memory array 100, and is bonded to the memory array 100. The memory array 100 and the periphery device 200 may also adopt other architecture forms, for example, a architecture form that the periphery device 200 is located below the memory array 100, i.e., a PUC (periphery under core array) architecture, or the periphery device 200 is disposed in juxtaposition to the memory array 100, i.e., a PNC (periphery near core array) architecture, etc., which is not defined specifically herein.

According to the memory provided by the examples of the present application, the reliability and electrical performance of the memory can be improved.

Refer to FIG. 7, which is a structural schematic diagram of a memory system provided by examples of the present application.

As shown in FIG. 7, examples of the present application further provide a memory system which comprises a memory 300 and a controller 400, wherein the memory 300 is electrically connected with the controller 400, and the controller 400 is used to control the memory 300 to store data. The memory 300 is the memory in the above-mentioned examples, which is no longer repeated in detail here. The controller 400 may be a controller well known to those skilled in the art, which is no longer repeated in detail here.

The memory system may be applied to end products, such as a computer, a television, a set-top box, a vehicle-mounted product, etc.

The present application provides semiconductor devices and fabrication methods of the semiconductor devices, a memories and a memory systems, which can increase size uniformity of gate structures, improve the performance of the memory and reduce fabrication difficulty.

According to one example, the present application provides a fabrication method of a semiconductor device, which comprises: providing a substrate; forming a stop layer on a side of the substrate; forming a semiconductor layer on a side of the stop layer facing away from the substrate; forming first through-holes penetrating through the semiconductor layer and the stop layer; and forming gate structures on part of inner walls and part of bottoms of the first through-holes.

Optionally, the stop layer comprises drains.

Optionally, forming the first through-holes penetrating through the semiconductor layer and the stop layer comprises: forming a mask layer on a side of the semiconductor layer facing away from the substrate, the mask layer comprising openings; and forming, through the openings, the first through-holes penetrating through the semiconductor layer and the stop layer; after forming the gate structures on part of the inner walls and part of the bottoms of the first through-holes, the method further comprises: removing the mask layer.

Optionally, the first through-holes comprise first sub-holes penetrating through the semiconductor layer and third sub-holes penetrating through the stop layer; forming the first through-holes penetrating through the semiconductor layer and the stop layer comprises: forming the first sub-holes penetrating through the semiconductor layer and second sub-holes penetrating through the stop layer; and etching the stop layer exposed in the second sub-holes to form the third sub-holes, dimensions of ends of the third sub-holes close to the first sub-holes being greater than dimensions of ends of the first sub-holes close to the third sub-holes.

Optionally, forming the gate structures on part of the inner walls and part of the bottoms of the first through-holes comprises: forming initial gate structures on the inner walls and the bottoms of the first through-holes, the bottoms of the first through-holes being ends of the first through-holes close to the substrate; removing part of the initial gate structures on the inner walls of the first through-holes to obtain remaining initial gate structures, the part of the initial gate structures being located at ends of the initial gate structures facing away from the substrate; and removing part of the remaining initial gate structures on the inner walls and the bottoms of the first through-holes to separate each of the remaining initial gate structures into two gate structures.

Optionally, the method further comprises: forming second through-hole penetrating through the semiconductor layer and the stop layer while forming the first through-holes, the second through-hole being located between two adjacent ones of the first through-holes; before forming the gate structures on part of the inner walls and part of the bottoms of the first through-holes, the method further comprises: forming an isolation structure in the second through-hole.

Optionally, the method further comprises: forming sources in the semiconductor layer, the sources being located on a side of the semiconductor layer facing away from the substrate.

Optionally, the gate structures comprise a gate oxidization layer on part of the inner walls and part of the bottoms of the first through-holes, and a gate layer on a side of the gate oxidization layer facing away from the semiconductor layer.

Optionally, the method further comprises: forming spacing portions within the first through-holes.

Optionally, the stop layer comprises at least one of monocrystalline silicon, polycrystalline silicon, monocrystalline germanium, and silicon germanium.

Accordingly, the present application further provides a semiconductor device, comprising: a base; a stop layer located on a side of the base; a semiconductor layer located on a side of the stop layer facing away from the base; and gate structures extending in the semiconductor layer and penetrating through the stop layer.

Optionally, the gate structures comprise first substructures extending in the semiconductor layer along a first direction, second substructures extending in the stop layer along the first direction, and third substructures and fourth substructures that extend in the stop layer along a second direction, the first direction intersecting the second direction; an end of each of the first substructures is connected with an end of each of the third substructures; ends of the third substructures facing away from the first substructures are connected with ends of the second substructures; and ends of the second substructures facing away from the third substructures are connected with ends of the fourth substructures.

Optionally, the semiconductor device further comprises spacing portions, wherein the spacing portions extend in the semiconductor layer and the stop layer along a first direction; the gate structures cover part of sidewalls and part of bottoms of the spacing portions; and the bottoms of the spacing portions are ends of the spacing portions close to the base.

Optionally, the spacing portions comprise first spacing sub-portions penetrating through the semiconductor layer, and second spacing sub-portions extending in the stop layer along the first direction; dimensions of ends of the second spacing sub-portions close to the first spacing sub-portions in a second direction are greater than dimensions of ends of the first spacing sub-portions close to the second spacing sub-portions in the second direction, and the second direction intersects the first direction.

Optionally, the gate structures comprise a gate oxidization layer extending in the semiconductor layer along the first direction and penetrating through the stop layer, and a gate layer located on a side of the gate oxidization layer facing away from the semiconductor layer.

Optionally, the stop layer comprises drains.

Optionally, the semiconductor layer comprises sources that are located on a side of the semiconductor layer facing away from the base.

Optionally, the semiconductor device further comprises an isolation structure, wherein the isolation structure penetrate through the semiconductor layer and the stop layer.

Optionally, the stop layer comprises at least one of monocrystalline silicon, polycrystalline silicon, monocrystalline germanium, and silicon germanium.

Accordingly, the present application further provides a memory, comprising: a memory array comprising the above-mentioned semiconductor device; and a periphery device bonded to the memory array.

Accordingly, the present application further provides a memory system, comprising: the above-mentioned memory; and a controller connected with the memory.

The examples of the present application provide a semiconductor device and a fabrication method of the semiconductor device, a memory and a memory system, which can form a stop layer on a side of a substrate, form a semiconductor layer on a side of the stop layer facing away from the substrate to form first through-holes penetrating through the semiconductor layer and the stop layer, and form gate structures on part of inner walls and part of bottoms of the first through-holes. The disposition of the stop layer can increase uniformity of the depths of the first through-holes, thereby increasing uniformity of the dimensions of the gate structures in the first through-holes, improving performance of the memory and reducing the fabrication difficulty.

Although the present application has been disclosed as above with examples, the above examples are not used to limit the present application. Those of ordinary skill in the art may make various changes and modifications without departing from the spirits and scope of the present application. Therefore, the protection scope of the present application shall be defined by the claims.

What is claimed is:

1. A fabrication method of a semiconductor device, comprising:
providing a substrate;
forming a stop layer on a side of the substrate;
forming a semiconductor layer on a side of the stop layer facing away from the substrate;
forming a first through-hole penetrating through the semiconductor layer and the stop layer; and
forming a gate structure on part of an inner wall and part of a bottom of the first through-hole.

2. The fabrication method of the semiconductor device of claim 1, wherein the stop layer comprises a drain.

3. The fabrication method of the semiconductor device of claim 1, wherein forming the first through-hole penetrating through the semiconductor layer and the stop layer comprises:
forming a mask layer on a side of the semiconductor layer facing away from the substrate, the mask layer comprising an opening; and
forming the first through-hole penetrating through the semiconductor layer and the stop layer through the opening;
after forming the gate structure on part of the inner wall and part of the bottom of the first through-hole, the method further comprises:
removing the mask layer.

4. The fabrication method of the semiconductor device of claim 1, wherein the first through-hole comprises a first sub-hole penetrating through the semiconductor layer and a third sub-hole penetrating through the stop layer;
forming the first through-hole penetrating through the semiconductor layer and the stop layer comprises:
forming the first sub-hole penetrating through the semiconductor layer and a second sub-hole penetrating through the stop layer; and
etching the stop layer exposed in the second sub-hole to form the third sub-hole, dimensions of ends of the third sub-hole close to the first sub-hole being greater than dimensions of ends of the first sub-hole close to the third sub-hole.

5. The fabrication method of the semiconductor device of claim 1, wherein forming the gate structure on part of the inner wall and part of the bottom of the first through-hole comprises:
forming an initial gate structure on the inner wall and the bottom of the first through-hole, the bottom of the first through-hole being an end of the first through-hole close to the substrate;
removing part of the initial gate structure on the inner wall of the first through-hole to obtain a remaining initial gate structure, the part of the initial gate structure being located at an end of the initial gate structure facing away from the substrate; and
removing part of the remaining initial gate structure on the inner wall and the bottom of the first through-hole to separate the remaining initial gate structure into two gate structures.

6. The fabrication method of the semiconductor device of claim 1, further comprising:
forming a second through-hole penetrating through the semiconductor layer and the stop layer while forming the first through-hole, the second through-hole being located between the two adjacent first through-holes;
before forming the gate structure on part of the inner wall and part of the bottom of the first through-hole, the method further comprises:
forming an isolation structure in the second through-hole.

7. The fabrication method of the semiconductor device of claim 1, comprising forming a source in the semiconductor layer, the source being located on a side of the semiconductor layer facing away from the substrate.

8. The fabrication method of the semiconductor device of claim 1, wherein the gate structure comprises a gate oxidization layer on part of the inner wall and part of the bottom of the first through-hole, and a gate layer on a side of the gate oxidization layer facing away from the semiconductor layer.

9. The fabrication method of the semiconductor device of claim 1, further comprising forming a spacing portion within the first through-hole.

10. The fabrication method of the semiconductor device of claim 1, wherein the stop layer comprises at least one of monocrystalline silicon, polycrystalline silicon, monocrystalline germanium, or silicon germanium.

11. A semiconductor device, comprising:
a base;
a stop layer located on a side of the base;
a semiconductor layer located on a side of the stop layer facing away from the base; and
a gate structure extending in the semiconductor layer and penetrating through the stop layer.

12. The semiconductor device of claim 11, wherein the gate structure comprises a first substructure extending in the semiconductor layer along a first direction, a second substructure extending in the stop layer along the first direction, and a third substructure and a fourth substructure that extend in the stop layer along a second direction, the first direction intersecting the second direction;
an end of each of the first substructure is connected with an end of the third substructure; an end of the third substructure facing away from the first substructure is connected with an end of the second substructure; and an end of the second substructure facing away from the third substructure is connected with an end of the fourth substructure.

13. The semiconductor device of claim 11, further comprising a spacing portion, wherein the spacing portion extends in the semiconductor layer and the stop layer along a first direction; the gate structure covers part of sidewall and part of bottom of the spacing portion; and the bottom of the spacing portion is an end of the spacing portion close to the base.

14. The semiconductor device of claim 13, wherein the spacing portion comprises a first spacing sub-portion penetrating through the semiconductor layer, and second spacing sub-portion extending in the stop layer along the first direction;
a dimension of an end of the second spacing sub-portion close to the first spacing sub-portion in a second direction are greater than a dimension of an end of the first spacing sub-portion close to the second spacing sub-portion in the second direction, and the second direction intersects the first direction.

15. The semiconductor device of claim 11, wherein the gate structure comprises a gate oxidization layer extending in the semiconductor layer along a first direction and penetrating through the stop layer, and a gate layer located on a side of the gate oxidization layer facing away from the semiconductor layer.

16. The semiconductor device of claim 11, wherein the stop layer comprises a drain.

17. The semiconductor device of claim 11, wherein the semiconductor layer comprises a source that is located on a side of the semiconductor layer facing away from the base.

18. The semiconductor device of claim 11, further comprising an isolation structure, wherein the isolation structure penetrates through the semiconductor layer and the stop layer.

19. The semiconductor device of claim 11, wherein the stop layer comprises at least one of monocrystalline silicon, polycrystalline silicon, monocrystalline germanium, or silicon germanium.

20. A memory system, comprising:
a memory including a memory array comprising a semiconductor device, wherein the semiconductor device comprises:
a base;
a stop layer located on a side of the base;
a semiconductor layer located on a side of the stop layer facing away from the base; and
a gate structure extending in the semiconductor layer and penetrating through the stop layer;
a periphery device bonded to the memory array; and
a controller connected with the memory.
